(19) United States
(12) Patent Application Publication
(10) Pub. No.: US 2022/0285588 A1
(43) Pub. Date: Sep. 8, 2022

(54) MULTI-SPECTRAL STEALTH DEVICE

(71) Applicant: INDUSTRY-ACADEMIC COOPERATION FOUNDATION YONSEI UNIVERSITY, Seoul (KR)

(72) Inventors: JAE WON HAHN, SEOUL (KR); JA GYEONG KIM, SEOUL (KR); CHANG HOON PARK, SEOUL (KR)

(21) Appl. No.: 17/647,955

(22) Filed: Jan. 13, 2022

(30) Foreign Application Priority Data
Mar. 4, 2021 (KR) 10-2021-0028667

(51) Int. Cl. H01L 33/50; G06K 15/02

(52) U.S. Cl. CPC H01L 33/50; G06K 15/1878; F41H 3/00

(57) ABSTRACT

Disclosed is a multi-spectral stealth device that generates a camouflage color in a visible ray region, has low reflectivity in near-infrared ray and short-wavelength infrared-ray regions, and has low emissivity in mid-wavelength and long-wavelength infrared-ray regions. The multi-spectral stealth device includes a metal layer made of a first metal having electrical conductivity; a semiconductor layer disposed on a top surface of the metal layer and made of a semiconductor material having a bandgap in which the semiconductor material is capable of absorbing a visible ray and a near-infrared ray; and a plurality of metal patterns regularly arranged on a top surface of the semiconductor layer and made of a second metal having electrical conductivity.

### CROSS-REFERENCE TO RELATED APPLICATION

This application claims a benefit under 35 U.S.C. § 119(a) of Korean Patent Application No. 10-2021-0028667 filed on Mar. 4, 2021, on the Korean Intellectual Property Office, the entirety of disclosure of which is incorporated herein by reference for all purposes.

### BACKGROUND

### Field

The present disclosure relates to a multi-spectral stealth device capable of generating a camouflage color and coping with an infrared-ray laser detector, a thermal infrared-ray detector, and the like.

### Description of Related Art

Development of military camouflage schemes generally proceeds toward a trend in which a camouflage color of an object that may be confused with colors of surroundings in the visible ray region may be generated, and detection of the object using infrared-ray radar detectors and thermal infrared-ray detectors may be lowered.

Thermal infrared-ray detectors in mid-wavelength infrared-ray (MWIR) and long-wavelength infrared-ray (LWIR) regions detect a target mainly based on a measuring result of thermal radiation emitted from the target. Most of infrared-ray radar detectors using near-infrared ray (NIR) and short-wavelength infrared-ray (SWIR) detect the target based on a measuring result of an infrared-ray signal reflected from the target.

Therefore, in order to reduce the detection of the object using the detectors over a wide spectral region from the near-infrared ray (NIR) to the long-wavelength infrared-ray (LWIR), an object surface should be capable of suppressing reflection of the near-infrared ray and the short-wavelength infrared-ray from the surface, while at the same time suppressing thermal radiation of the mid-wavelength and long-wavelength infrared-rays from the surface.

Recently, a plasmonic meta-surface scheme based on a MIM (metal-insulator-metal) structure has been proposed as means for suppressing the thermal radiation from the surface and avoiding detection of the object in a sensing region of an infrared-ray detector. A MIM nanostructure has controllability of spectral properties of absorption and reflection according to excitation of surface plasmonic polariton (SPP) and magnetic polariton (MP) within the MIM structure, and thus has been applied to multispectral engineering. However, the MIM meta-surface has a dielectric medium free of loss in visible and infrared-ray regions to causes only a limited number of resonance modes. Thus, the surface only absorbs light in a limited spectral region.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

One purpose of the present disclosure is to provide a multi-spectral stealth device which may generate a camouflage color of a visible ray region having a pixel size of a sub-wavelength scale using a metal-semiconductor-metal (MSM) meta-surface, and may have low reflectivity in near-infrared ray and short-wavelength infrared-ray regions and low emissivity in mid-wavelength and long-wavelength infrared-ray regions.

Purposes in accordance with the present disclosure are not limited to the above-mentioned purpose. Other purposes and advantages in accordance with the present disclosure as not mentioned above may be understood from following descriptions and more clearly understood from embodiments in accordance with the present disclosure. Further, it will be readily appreciated that the purposes and advantages in accordance with the present disclosure may be realized by features and combinations thereof as disclosed in the claims.

One aspect of the present disclosure provides a multi-spectral stealth device comprising: a metal layer made of a first metal having electrical conductivity; a semiconductor layer disposed on a top surface of the metal layer and made of a semiconductor material having a bandgap in which the semiconductor material is capable of absorbing a visible ray and a near-infrared ray; and a plurality of metal patterns regularly arranged on a top surface of the semiconductor layer and made of a second metal having electrical conductivity.

In one implementation, the semiconductor material transmits mid-wavelength and long-wavelength infrared-rays having a wavelength greater than 2 μm and smaller than or equal to 14 μm therethrough, and absorbs energy of at least a portion of a short-wavelength infrared-ray, a near-infrared ray and a visible ray having a wavelength smaller than or equal to 2 μm, wherein frequency-selective reflection of the infrared-ray occurs at an interface between the semiconductor layer and the metal layer.

In one implementation, reflection of the mid-wavelength and long-wavelength infrared-rays from the interface between the semiconductor layer and the metal layer is predominant over absorption or transmission of the mid-wavelength and long-wavelength infrared-rays into or through the interface between the semiconductor layer and the metal layer, wherein absorption or transmission of the short-wavelength infrared-ray, the near-infrared ray, and the visible ray into or through the interface between the semiconductor layer and the metal layer is predominant over reflection of the short-wavelength infrared-ray, the near-infrared ray, and the visible ray from the interface between the semiconductor layer and the metal.

In one implementation, the semiconductor layer is made of germanium (Ge).

In one implementation, a thickness of the semiconductor layer is in a range of 20 to 100 nm.

In one implementation, the plurality of metal patterns generate a camouflage color in a visible ray region via plasmonic resonance.

In one implementation, each of the plurality of metal patterns has a diameter in a range of 100 to 500 nm and a circular disk shape having a thickness in a range of 50 to 100 nm.

In one implementation, a pitch as a spacing between centers of two adjacent metal patterns of the plurality of metal patterns is in a range of 200 to 10000 nm.

In one implementation, the plurality of metal patterns include: first metal patterns disposed in a first area to generate a first camouflage color; and second metal patterns disposed in a second area positioned adjacent to the first area, wherein the second metal patterns generate a second camouflage color different from the first camouflage color, wherein at least one of a diameter, a thickness, and a pitch of the second metal patterns is different from at least one of a diameter, a thickness, and a pitch of the first metal patterns.

In one implementation, 20 to 60% of a surface of the semiconductor layer is covered with the metal pattern.

In one implementation, the device further comprises: a substrate disposed on a bottom face of the metal layer; and an adhesive layer disposed between the metal layer and the substrate for bonding the metal to the substrate.

The multi-spectral stealth device according to the embodiments may generate a camouflage color of a visible ray region having a pixel size of a sub-wavelength scale using a metal-semiconductor-metal (MSM) meta-surface. The multi-spectral stealth device may have low reflectivity and high absorptivity in near-infrared ray and short-wavelength infrared-ray regions. Thus, the multi-spectral stealth device may achieve a stealth function against infrared-ray laser tracking systems, SWIR cameras, night vision goggles, etc. The multi-spectral stealth device may exhibit high reflectivity and low emissivity in the mid-wavelength and long-wavelength infrared-ray regions. Thus, the device may achieve the stealth function against the thermal imaging devices, etc.

In addition to the effects as described above, specific effects in accordance with the present disclosure will be described together with following detailed descriptions for carrying out the disclosure.

### BRIEF DESCRIPTION OF DRAWINGS

FIG. 1 is a cross-sectional view for illustrating a multi-spectral stealth device according to an embodiment of the present disclosure.

FIG. 2A is a diagram showing optical power distribution of a multi-spectral stealth device according to an embodiment under a LSPR (localized surface plasmon resonance) condition exhibiting a maximum spectral absorptivity.

FIG. 2B is a diagram showing color distribution of a multi-spectral stealth device according to an embodiment based on a varying radius of a metal pattern and a fill factor as a percentage at which the metal pattern occupies an area of a surface of a semiconductor layer.

FIG. 3A is a diagram showing power distribution of a multi-spectral stealth device according to an embodiment having a semiconductor layer with a thickness of 30 nm under a destructive interference condition of a near-infrared ray region.

FIG. 3B is a diagram showing an absorption spectrum in a near-infrared ray region of each of multi-spectral stealth devices according to an embodiment having semiconductor layers of different thicknesses, respectively.

FIG. 4A is a diagram showing power distribution of each of multi-spectral stealth devices according to an embodiment having metal patterns of 185 nm and 175 nm radius, respectively, under a gap plasmon resonance condition in a short-wavelength infrared-ray region.

FIG. 4B and FIG. 4C are diagrams showing calculated absorption spectra and measured absorption spectra in a short-wavelength infrared-ray region of multi-spectral stealth devices according to an embodiment generating red, green, and blue color, respectively.

FIG. 5 is a diagram showing emissivity in mid-wavelength and long-wavelength infrared-ray regions of each of multi-spectral stealth devices according to an embodiment rendering different camouflage colors.

### DETAILED DESCRIPTION

For simplicity and clarity of illustration, elements in the FIGS. are not necessarily drawn to scale. The same reference numbers in different FIGS. represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

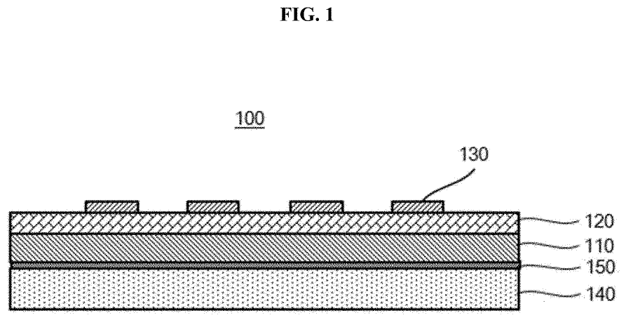

FIG. 1 is a cross-sectional view for illustrating a multi-spectral stealth device according to an embodiment of the present disclosure.

Referring to FIG. 1, a multi-spectral stealth device 100 according to an embodiment of the present disclosure may include a metal layer 110, a semiconductor layer 120, and a metal pattern 130.

The stealth device 100 according to this embodiment may be disposed on a surface of an object (not shown), and may exhibit a stealth function against an infrared-ray laser-guided weapon and an infrared-ray image-guided weapon that detects thermal infrared-ray and may render a camouflage color in the visible ray region.

The metal layer 110 may be made of a metal material having low absorptivity and high reflectivity in an infrared-ray region having a wavelength greater than 3 μm, such as mid-wavelength infrared-ray and long-wavelength infrared-ray regions. For example, the metal layer 110 may be made of silver (Ag), aluminum (Al), platinum (Pt), or the like.

In one embodiment, a thickness of the metal layer 110 is not particularly limited. In an embodiment, the metal layer 110 may be formed to have a thickness of about 50 nm or greater, for example, a range of about 150 to 300 nm.

The semiconductor layer 120 may be disposed on the metal layer 110 and may be made of a semiconductor material having a bandgap in which the material may be capable of absorbing the visible ray and the near-infrared ray. In one embodiment, the semiconductor layer 120 may be made of germanium (Ge). A thickness of the semiconductor layer 120 may be smaller than a wavelength of the mid-wavelength infrared-ray. For example, the semiconductor layer 120 may be formed to a thickness in a range of about 20 to 100 nm.

The semiconductor layer 120 acts as a medium having high transparency and thus free of loss in a mid-wavelength infrared-ray (MWIR) region having a wavelength of about 3 to 8 μm and a long-wavelength infrared-ray region having a wavelength of about 8 to 14 μm, while acting as a medium opaque and thus causing loss in a ray region in a wavelength of about 2 μm, for example, the visible ray, the near-infrared ray, and the infrared-ray having a wavelength of about 1.4 to 2 μm in the short-wavelength infrared-ray. Accordingly, when the semiconductor layer 120 is stacked on the metal layer 110, a non-negligible reflective phase shift in the infrared-ray region may occur at an interface between the semiconductor layer 120 and the metal layer 110. Thus, frequency selective reflection may occur at the interface. As a result, reflectivity in the near-infrared ray and the short-wavelength infrared-ray regions may be lowered, while reflectivity in the mid-wavelength or long-wavelength infrared-ray region may be increased.

That is, when the mid-wavelength infrared-ray and long-wavelength infrared-ray are incident to the device, the mid-wavelength infrared-ray and the long-wavelength infrared-ray may not be absorbed into the semiconductor layer 120, and may be reflected from the interface between the metal layer 110 and the semiconductor layer 120. This may lower the emissivity of the object, thereby reducing the detection of the object by a thermal imaging camera. Further, when the near-infrared ray and short-wavelength infrared-ray are incident thereto, the semiconductor layer 120 may absorb the near-infrared ray and short-wavelength infrared-ray, thereby reducing reflectivity of light in the near-infrared ray and short-wavelength infrared-ray regions. As a result, the device may reduce the detection of the object by night vision goggles, short-wavelength infrared-ray (SWIR) cameras, infrared-ray laser tracking systems, and the like.

The metal pattern 130 may be disposed on the surface of the semiconductor layer 120, and may be made of a metal having electrical conductivity. For example, the metal pattern 130 may be made of a metal such as aluminum (Al), gold (Au), or platinum (Pt).

In an embodiment, a plurality of metal patterns 130 may be regularly arranged on the surface of the semiconductor layer 120. Thus, the device 100 may generate a camouflage color in the visible ray region having a pixel size of a sub-wavelength scale via plasmonic resonance.

In one embodiment, each of the plurality of metal patterns 130 may have a circular disk shape having a diameter of about 100 to 500 nm and a thickness of about 50 to 100 nm. The plurality of metal patterns 130 may be arranged such that a pitch as a spacing between centers of two adjacent metal patterns may be in a range of about 300 to 800 nm.

A plasmonic resonance wavelength caused by the metal pattern 130 and the semiconductor layer 120 disposed thereunder may be adjusted based on parameters such as a size, a thickness, and a pitch of the metal patterns 130. As a result, various camouflage colors may be generated by adjusting the parameters. In one embodiment, as the size of the metal pattern 130 increases, a size of the plasmonic resonance wavelength may increase, while a wavelength of the reflected light may decrease.

In an embodiment, about 20 to 60% of a surface of the semiconductor layer 140 may be covered with the metal pattern 130. As a fill factor as a percentage at which the metal pattern 130 covers an area of the surface of the semiconductor layer 140 increases, a range and sharpness of the generated camouflage color may be improved. However, when the fill factor of the metal pattern 130 exceeds 60% of the surface of the semiconductor layer 140, a problem in that reflectance of the near-infrared ray and short-wave infrared-ray increases may occur.

In one embodiment, the multi-spectral stealth device 100 according to an embodiment of the present disclosure may further include a substrate 140. The metal layer 110 may be adhered to the substrate 140 via an adhesive layer 150.

A material and a structure of the substrate 140 are not particularly limited as long as the substrate may support a stack structure of the metal layer 110, the semiconductor layer 120, and the metal pattern 130 thereon. For example, the substrate 140 may be made of a metal material, a semiconductor material, a polymer material, or the like.

In one example, the substrate 140 may act as a component separate from the object to which the multi-spectral stealth device 100 of the present disclosure is applied. In another example, a surface of the object may function as the substrate 140.

The multi-spectral stealth device according to the embodiments may generate a camouflage color of a visible ray region having a pixel size of a sub-wavelength scale using a metal-semiconductor-metal (MSM) meta-surface. The multi-spectral stealth device may have low reflectivity and high absorptivity in near-infrared ray and short-wavelength infrared-ray regions. Thus, the multi-spectral stealth device may achieve a stealth function against infrared-ray laser tracking systems, SWIR cameras, night vision goggles, etc. The multi-spectral stealth device may exhibit high reflectivity and low emissivity in the mid-wavelength and long-wavelength infrared-ray regions. Thus, the device may achieve the stealth function against the thermal imaging devices, etc.

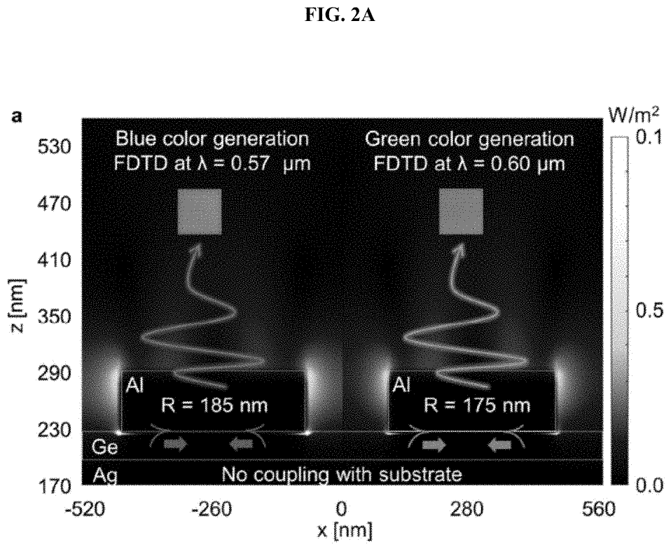

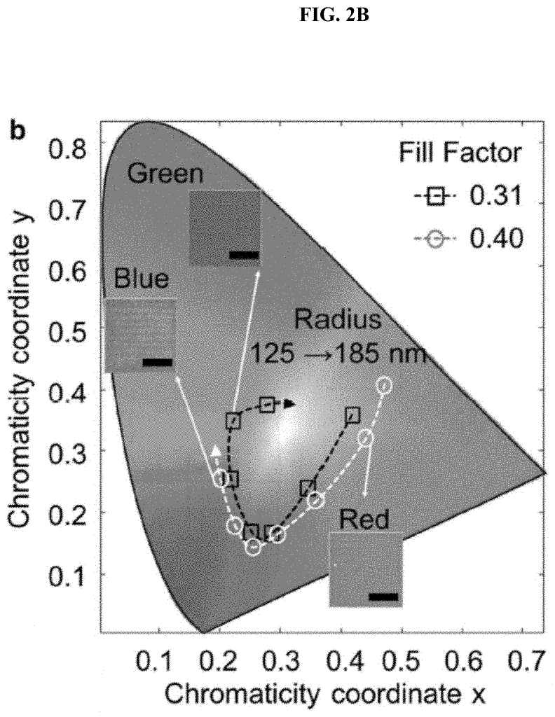

FIG. 2A is a diagram showing optical power distribution of a multi-spectral stealth device according to an embodiment under a LSPR (localized surface plasmon resonance) condition exhibiting a maximum spectral absorptivity. FIG. 2B is a diagram showing color distribution of a multi-spectral stealth device according to an embodiment based on a varying radius of a metal pattern and a fill factor as a percentage at which the metal pattern occupies an area of a surface of a semiconductor layer. In this connection, the metal layer, the semiconductor layer, and the metal pattern of the multi-spectral stealth device according to the above embodiment were respectively made of silver (Ag), germanium (Ge), and aluminum (Al), and the radius of the metal pattern varied in a range from 125 nm to 185 nm.

Referring to FIG. 2A and FIG. 2B, because the semiconductor layer is opaque in a visible ray frequency region, optical energy may not be transmitted to the underlying metal surface, and the LSPR (localized surface plasmon resonance) may depend mainly on the metal pattern.

To evaluate a color perceived by the human eye, tristimulus values defined using a following Equation were calculated based on reflection spectrum from the MSM meta-surface. For color evaluation, a constant source power distribution was assumed in color analysis.

M=∫I(λ)R(λ)m̅(λ)dλ, where M=X,Y,Z in a CIR color space. [Equation 1]

In the above Equation 1, I represents the source power distribution, R represents reflectivity of a sample, and m represents a color matching function of CIE.

It was identified that changing the size of the metal pattern may allow the LSPR wavelength to vary, and as a result, the multi-spectral stealth device according to the above example may generate various colors from red to green to blue. In particular, as the radius of the metal pattern increased, a shift of the LSPR wavelength to red was caused. An evaluated color varied in a range from red to blue to green. As the radius of the metal pattern decreased, a wavelength of the reflected light increased, and as a result, green or red light was generated.

In one example, in a plasmonic resonator composed of “a precious metal pattern and a dielectric material free of loss”, low ohmic loss causes an absorption spectrum with a sharp bandwidth and a reflection spectrum with a wide bandwidth, such that color saturation is deteriorated. To the contrary, the semiconductor layer in the MSM meta-surface according to the present disclosure acts as the medium causing the loss, and thus causes an absorption spectrum with a wider bandwidth and a reflection spectrum with a narrow bandwidth, thereby enhancing the color saturation.

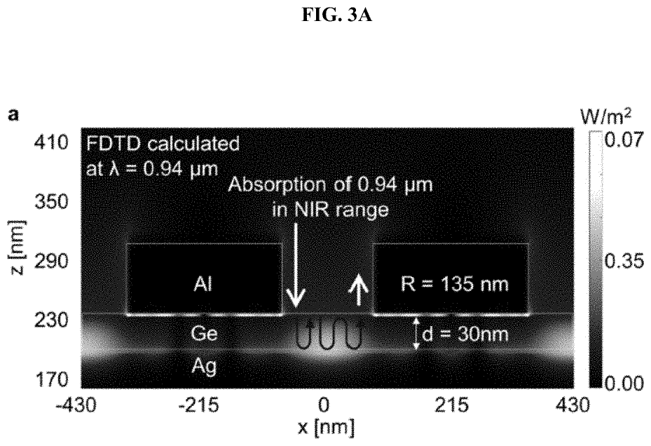

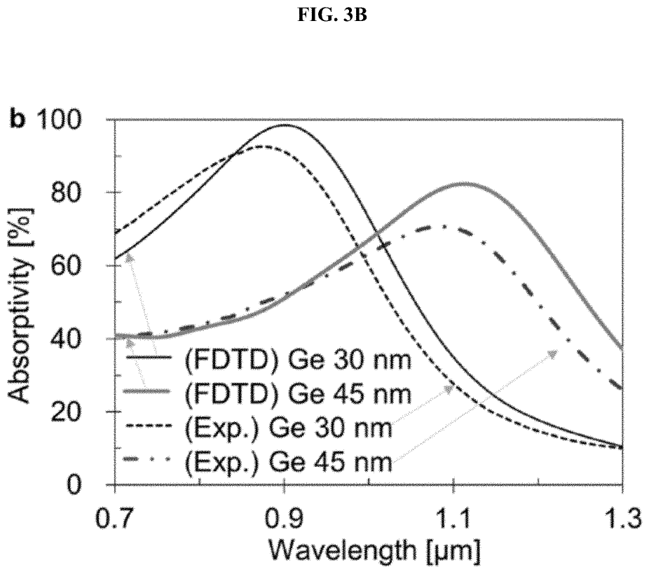

FIG. 3A is a diagram showing power distribution of a multi-spectral stealth device according to an embodiment having a semiconductor layer with a thickness of 30 nm under a destructive interference condition of a near-infrared ray region. FIG. 3B is a diagram showing an absorption spectrum in a near-infrared ray region of each of multi-spectral stealth devices according to an embodiment having semiconductor layers of different thicknesses, respectively. The metal layer, the semiconductor layer, and the metal pattern of the multi-spectral stealth device according to this embodiment were made of silver (Ag), germanium (Ge), and aluminum (Al), respectively.

Referring to FIG. 3A and FIG. 3B, although the semiconductor layer made of germanium (Ge) acts as a highly conductive medium having opaque properties in the near-infrared ray (NIR) region, optical energy is effectively captured inside the semiconductor layer, and as a result, reflection of the near-infrared ray from the multi-spectral stealth device according to the embodiment is remarkably suppressed. In one example, optical energy absorption in the near-infrared ray region into the metal pattern is found to be negligible.

In the multi-spectral stealth device according to the embodiment, a destructive interference condition is determined based on an optical path length (OPL) represented as ‘n_{Ge}t_{Ge}’, where n denotes reflectance, t denotes a thickness of a layer, and a subscript denotes a material. A phase shift is induced due to reflection at the interface between the semiconductor layer and the metal layer.

Unlike a perfect reflector at the interface between the dielectric material free of the loss and the metal layer, a high imaginary value of a refractive index relative to the germanium based semiconductor layer causes a phase shift that may not be negligible. This results in an out of phase condition with a very short OPL. Therefore, despite the fact that the thickness of the semiconductor layer is of a nanometer scale, the destructive interference condition is satisfied. As the thickness of the semiconductor layer increases, the shift of the resonance to red is caused. However, due to the low conductivity of germanium in the near-infrared ray region, a magnitude of a maximum absorption peak decreases as the thickness of the semiconductor layer increases.

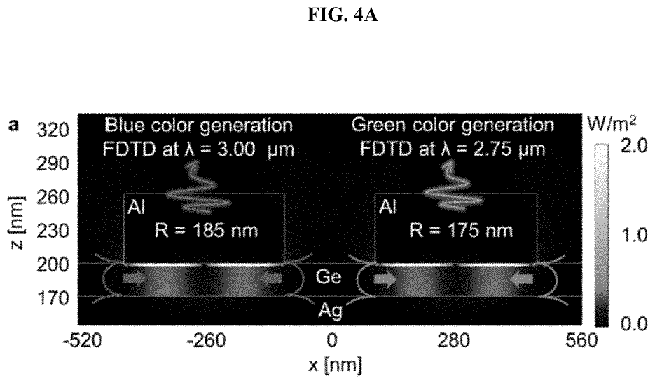

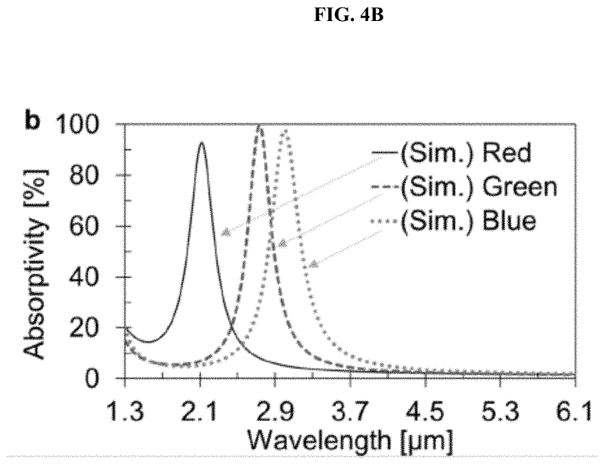

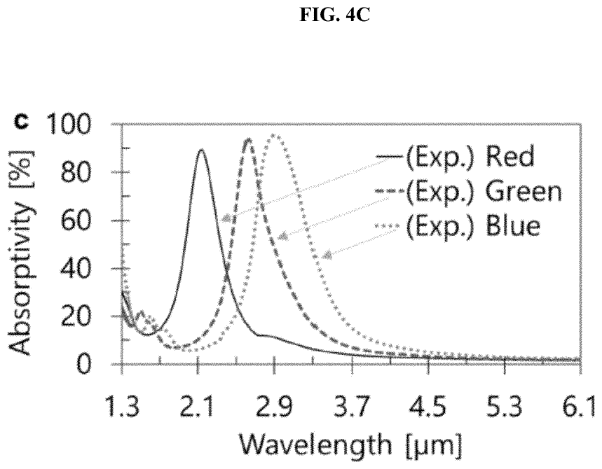

FIG. 4A is a diagram showing power distribution of each of multi-spectral stealth devices according to an embodiment having metal patterns of 185 nm and 175 nm radius, respectively, under a gap plasmon resonance condition in a short-wavelength infrared-ray region. FIG. 4B and FIG. 4C are diagrams showing calculated absorption spectra and measured absorption spectra in a short-wavelength infrared-ray region of multi-spectral stealth devices according to an embodiment generating red, green, and blue color, respectively. The metal layer, the semiconductor layer, and the metal pattern of the multi-spectral stealth device according to this embodiment were made of silver (Ag), germanium (Ge), and aluminum (Al), respectively.

Referring to FIG. 4A to FIG. 4C, germanium acts as a material free of the loss in the short-wavelength infrared-ray (SWIR) region other than the near-infrared ray region. Thus, in the multi-spectral stealth device according to this embodiment, a gap plasmon mode may be allowed in the short-wavelength infrared-ray (SWIR) region. As shown in FIG. 4A, the optical power is effectively confined inside the semiconductor layer under the gap plasmonic resonance condition.

Because a gap plasmonic resonance wavelength is affected with a lateral dimension of a structure as well as the thickness of the semiconductor layer, the metal pattern of the multi-spectral stealth device according to the embodiment rendering a blue color has a relatively large radius, and thus the gap plasmonic resonance is observed in a long wavelength region.

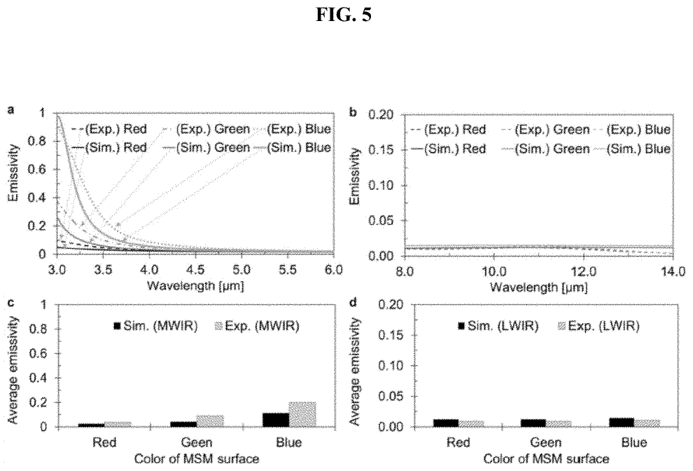

FIG. 5 is a diagram showing emissivity in mid-wavelength and long-wavelength infrared-ray regions of each of multi-spectral stealth devices according to an embodiment rendering different camouflage colors.

Referring to FIG. 5, conductivity of the germanium-based semiconductor layer in the wavelength region from the mid-wavelength infrared-ray (MWIR) region to the long-wavelength infrared-ray (LWIR) region is negligible. As a result, the semiconductor layer acts as the dielectric layer having high transparency and free of the loss. Therefore, the stack structure of the semiconductor layer/metal layer may act as a reflective substrate causing low-loss and free of wavelength-selective performance in a wavelength region from the wavelength infrared-ray (MWIR) to the long-wavelength infrared-ray (LWIR). The stack structure may achieve high reflectivity in a non-resonant frequency region. Further, in this wavelength region, the thickness of the semiconductor layer is significantly smaller than the wavelengths of the mid-wavelength infrared-ray (MWIR) and the long-wavelength infrared-ray (LWIR), such that thin-film interference in the stack structure of the semiconductor layer/metal layer is negligible.

Band emissivity of the multi-spectral stealth device according to the implementation is found to be sufficiently low such that the object on which the device is applied is not detected by a thermal imaging camera-based sensing device. However, the band emissivity of the multi-spectral stealth device according to an embodiment having a larger metal pattern radius and thus rendering a blue camouflage color is found to be relatively slightly higher than that of the multi-spectral stealth device according to an embodiment having a smaller metal pattern radius and rendering a red camouflage color.

Further, because the gap plasmonic resonance wavelength is located in the short-wavelength infrared-ray (SWIR) region, a tail of the resonance may be present in the mid-wavelength infrared-ray (MWIR) region. As a result, thermal emissivity in the mid-wavelength infrared-ray (MWIR) region is relatively higher than thermal emissivity in the long-wavelength infrared-ray region. In particular, a geometric dimension of the meta-surface of the multi-spectral stealth device according to the embodiment is too small such that the device may not interact with incident light in the long-wavelength infrared-ray region. Thus, the multi-spectral stealth device according to the embodiment exhibits extremely low band emission in the long-wavelength infrared-ray region.

Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. A multi-spectral stealth device comprising:
a metal layer made of a first metal having electrical conductivity;
a semiconductor layer disposed on a top surface of the metal layer and made of a semiconductor material having a bandgap in which the semiconductor material is capable of absorbing a visible ray and a near-infrared ray; and
a plurality of metal patterns regularly arranged on a top surface of the semiconductor layer and made of a second metal having electrical conductivity.

2. The device of claim 1, wherein the semiconductor material transmits mid-wavelength and long-wavelength infrared-rays having a wavelength greater than 2 μm and smaller than or equal to 14 μm therethrough, and absorbs energy of at least a portion of a short-wavelength infrared-ray, a near-infrared ray and a visible ray having a wavelength smaller than or equal to 2 μm,
wherein frequency-selective reflection of the infrared-ray occurs at an interface between the semiconductor layer and the metal layer.

3. The device of claim 2, wherein reflection of the mid-wavelength and long-wavelength infrared-rays from the interface between the semiconductor layer and the metal layer is predominant over absorption or transmission of the mid-wavelength and long-wavelength infrared-rays into or through the interface between the semiconductor layer and the metal layer,
wherein absorption or transmission of the short-wavelength infrared-ray, the near-infrared ray, and the visible ray into or through the interface between the semiconductor layer and the metal layer is predominant over reflection of the short-wavelength infrared-ray, the near-infrared ray, and the visible ray from the interface between the semiconductor layer and the metal.

4. The device of claim 2, wherein the semiconductor layer is made of germanium (Ge).

5. The device of claim 2, wherein a thickness of the semiconductor layer is in a range of 20 to 100 nm.

6. The device of claim 1, wherein the plurality of metal patterns generate a camouflage color in a visible ray region via plasmonic resonance.

7. The device of claim 6, wherein each of the plurality of metal patterns has a diameter in a range of 100 to 500 nm and a circular disk shape having a thickness in a range of 50 to 100 nm.

8. The device of claim 7, wherein a pitch as a spacing between centers of two adjacent metal patterns of the plurality of metal patterns is in a range of 200 to 10000 nm.

9. The device of claim 8, wherein the plurality of metal patterns include:
first metal patterns disposed in a first area to generate a first camouflage color; and
second metal patterns disposed in a second area positioned adjacent to the first area, wherein the second metal patterns generate a second camouflage color different from the first camouflage color, wherein at least one of a diameter, a thickness, or a pitch of the second metal patterns is different from at least one of a diameter, a thickness, or a pitch of the first metal patterns.

10. The device of claim 7, wherein 20 to 60% of a surface of the semiconductor layer is covered with the metal pattern.

11. The device of claim 1, wherein the device further comprises:
a substrate disposed on a bottom face of the metal layer; and
an adhesive layer disposed between the metal layer and the substrate for bonding the metal to the substrate.
